(19) United States
(12) Patent Application Publication
(10) Pub. No.: US 2026/0293426 A1
(43) Pub. Date: Sep. 24, 2026

(54) HOLE TRANSPORT LAYER FOR LIGHT-EMITTING DEVICE, METHOD FOR PREPARING THE SAME, AND LIGHT-EMITTING DEVICE COMPRISING THE SAME

(71) Applicants: IUCF-HYU (Industry-University Cooperation Foundation Hanyang University), Seoul (KR); Foundation of Soongsil University-Industry Cooperation, Seoul (KR)

(72) Inventors: Tae-Hee HAN, Seoul (KR); Min-Ho PARK, Seoul (KR); Junsu YEO, Seoul (KR); Min Gyo KIM, Seoul (KR)

(21) Appl. No.: 19/564,645

(22) Filed: Mar. 12, 2026

(30) Foreign Application Priority Data
Mar. 12, 2025 (KR) 10-2025-0032331
Mar. 11, 2026 (KR) 10-2026-0043806

(51) Int. Cl. H10K 50/15; H10K 85/10

(52) U.S. Cl. CPC H10K 50/15; H10K 85/1135; H10K 85/141

(57) ABSTRACT

Disclosed are a hole transport layer for an optoelectronic device, a method for preparing the same, and an optoelectronic device including the same. The hole transport layer for an optoelectronic device is a single composite layer having a first surface and a second surface located opposite the first surface; wherein the single composite layer includes a p-type conductive polymer, an n-type metal oxide, and a perfluorinated compound, and has a vertical composition gradient in which a concentration of the n-type metal oxide gradually decreases and a concentration of the perfluorinated compound gradually increases along a thickness direction from the first surface toward the second surface.

### CROSS-REFERENCE TO RELATED APPLICATION

This application claims priority to and the benefit of Korean Patent Application No. 10-2025-0032331 filed with the Korean Intellectual Property Office on Mar. 12, 2025, and Korean Patent Application No. 10-2026-0043806 filed with the Korean Intellectual Property Office on Mar. 11, 2026, the entire contents of which are incorporated herein by reference.

### BACKGROUND OF THE INVENTION

### (a) Field of the Invention

A hole transport layer for an optoelectronic device, a method for preparing the same, and an optoelectronic device comprising the same are disclosed.

### (b) Description of the Related Art

With the development of next-generation display and lighting technology, technical demands for high-performance optoelectronic devices are continuously increasing. Perovskite is attracting attention as a key material for such optoelectronic devices, and its potential is highly evaluated because it may be manufactured in the form of a thin film through a low-cost solution process. However, when forming a perovskite thin film by a solution process, defects in the material itself or non-uniformity of the thin film, which inevitably occur, have been pointed out as common problems that degrade the luminous efficiency and stability of the device.

The efficiency and stability of such a device largely depend on the performance of a hole transport layer (HTL) between an anode and an emissive layer. An ideal hole transport layer should smoothly receive hole injection from the anode and efficiently transport them to the emissive layer. However, PEDOT:PSS, which is used as a universal hole transport layer material, has a relatively low work function and forms a high hole injection barrier at the interface with the emissive layer, which causes an increase in the driving voltage and a decrease in the efficiency of the device.

To solve this problem, attempts have been made to mix an n-type metal oxide (for example, MoOₓ) having a high work function with PEDOT:PSS, but this caused another serious problem. As conductive metal oxide particles are directly exposed to the interface with the emissive layer, an interfacial exciton quenching phenomenon occurs in which excitons generated in the emissive layer are annihilated without being converted into light. This phenomenon acts as a limitation that fundamentally lowers the luminous efficiency of the device.

Therefore, to implement a high-performance light-emitting device, a hole transport layer must simultaneously satisfy conflicting properties: high ‘internal conductivity’ for efficient hole transport and an ‘insulating surface’ for exciton quenching suppression. Since it is difficult to implement such multi-functionality in a single layer with existing single materials or simple mixture structures, there is a need for the development of hole transport layer materials and structures with a new concept.

### SUMMARY OF THE INVENTION

An embodiment aims to provide a hole transport layer for an optoelectronic device that simultaneously implements efficient hole injection and transport properties and exciton quenching suppression properties at the interface in a single layer.

An embodiment provides a hole transport layer for an optoelectronic device, which is a single composite layer having a first surface and a second surface located opposite the first surface; wherein the single composite layer includes a p-type conductive polymer, an n-type metal oxide, and a perfluorinated compound, and has a vertical composition gradient in which a concentration of the n-type metal oxide gradually decreases and a concentration of the perfluorinated compound gradually increases along a thickness direction from the first surface toward the second surface.

An embodiment may provide a hole transport layer for an optoelectronic device that simultaneously implements efficient hole injection and transport properties and exciton quenching suppression properties at the interface in a single layer.

### BRIEF DESCRIPTION OF THE DRAWINGS

FIG. 1 is a schematic view showing the structure of a perovskite light-emitting device including a self-assembled organic-inorganic hole transport layer according to an embodiment of the present invention.

FIG. 2 shows a transmission electron microscopy (TEM) image and a selected area electron diffraction (SAED) pattern showing the microstructure and crystallinity of molybdenum oxide (MoOₓ) nanoparticles prepared according to a preparation example of the present invention.

FIG. 3A and FIG. 3B are X-ray Photoelectron Spectroscopy (XPS) spectra comparing and analyzing the chemical composition and oxidation state of high-oxidant and low-oxidation state (Mo⁵⁺)-based metal oxide molybdenum oxide (MoOₓ) nanoparticles prepared according to Preparation Example 1 and Preparation Example 2 of the present invention.

FIG. 4 is a photograph comparing the appearances of the MoOₓ nanoparticle dispersions prepared in Preparation Example 1 and Preparation Example 2 of the present invention, showing the color difference between the SOH—H dispersion (yellow) in which MoO6+ is dominant and the SOH-L dispersion (dark blue) rich in Mo⁵⁺.

FIG. 5 is an ultraviolet photoelectron spectroscopy (UPS) spectrum measuring the work function and valence band levels of thin films formed by coating the MoOₓ nanoparticle dispersions according to Preparation Example 1 (SOH—H) and Preparation Example 2 (SOH-L) of the present invention.

FIG. 6 is a schematic view and an energy band diagram for explaining the energy band alignment between a conductive polymer (PEDOT:PSS) and MoOₓ nanoparticles and a charge exchange mechanism by oxygen vacancies in a hole transport layer according to Example of the present invention.

FIG. 7 is a depth-profiling UPS graph showing the work function change according to the depth direction of a self-assembled organic-inorganic hole transport layer according to Example (Example 2) of the present invention, showing the formation of energy levels according to the vertical composition gradient within the thin film.

FIG. 8 is a schematic view of an interfacial structure for explaining the principle by which a perfluorinated compound (PFSA) layer disposed on the surface of a self-assembled organic-inorganic hole transport layer suppresses an exciton quenching phenomenon at the interface with an emissive layer according to an embodiment of the present invention.

FIG. 9 is a time-resolved photoluminescence (TRPL) graph measuring the PL life-span of an emissive layer formed on a hole transport layer according to Examples and Comparative Examples of the present invention, showing the effect of suppressing interfacial exciton quenching according to the amount of the perfluorinated compound.

FIG. 10 is a graph showing the effect of improving device performance of the hole transport layer according to the present invention by comparing current-voltage-luminance (J-V-L) characteristics and current efficiency of a perovskite light-emitting device including the hole transport layer according to an embodiment and a comparative example of the present invention.

FIG. 11 is a schematic view and an energy band diagram for explaining the cause of device efficiency degradation due to interfacial exciton quenching and a high hole injection barrier occurring in a light-emitting device applying a conventional hole transport layer (PEDOT:PSS).

FIG. 12 is a schematic view showing the principle of self-assembly of components and vertical composition gradient formation within a hole transport layer according to an embodiment of the present invention.

### DETAILED DESCRIPTION OF THE EMBODIMENTS

Hereinafter, embodiments of the present invention will be described in detail. However, this is presented as an example, and the present invention is not limited thereby, and the present invention is only defined by the scope of the claims to be described later.

As used herein, when specific definition is not otherwise provided, it will be understood that when an element such as a layer, film, region, or substrate is referred to as being “on” another element, it can be directly on the other element or intervening elements may also be present.

As used herein, when specific definition is not otherwise provided, expressions in the singular may also include the plural. In addition, unless otherwise specified, “A or B” may mean “including A, including B, or including both A and B.”

As used herein, “a combination thereof” may mean a mixture of constituents, a laminate, a composite, a copolymer, an alloy, a blend, a reaction product, and the like.

### (Hole Transport Layer)

An embodiment provides a hole transport layer for an optoelectronic device, which is a single composite layer having a first surface and a second surface located opposite the first surface; wherein the single composite layer includes a p-type conductive polymer, an n-type metal oxide, and a perfluorinated compound, and has a vertical composition gradient in which a concentration of the n-type metal oxide gradually decreases and a concentration of the perfluorinated compound gradually increases along a thickness direction from the first surface toward the second surface.

By having the above configuration, an embodiment may provide a hole transport layer for an optoelectronic device that simultaneously implements efficient hole injection and transport properties and exciton quenching suppression properties at the interface in a single layer.

Hereinafter, the hole transport layer for an optoelectronic device of an embodiment will be described in detail.

p-type Conductive Polymer

The p-type conductive polymer serves as a main path through which holes move within the hole transport layer, and may act as a matrix in which other components may be dispersed.

The p-type conductive polymer may be a material that may be formed into a thin film through a solution process. An example of the p-type conductive polymer is PEDOT:PSS (Poly(3,4-ethylenedioxythiophene) polystyrene sulfonate). PEDOT:PSS is provided in the form of an aqueous dispersion, so it is easy to process and may show excellent thin film forming ability.

In addition, it may include any one or more of sulfonated polystyrene, polyaniline, or a self-doped polymer including polypyrrole, polythiophene, polyphenylene, polyphenylene vinylene, polystyrene, polyacetylene, PTAA (poly[bis(4-phenyl)(2,4,6-trimethylphenyl)amine]), and a derivative thereof, but is not limited thereto.

n-Type Metal Oxide

The n-type metal oxide may serve to improve electrical conductivity inside the hole transport layer through interaction with the p-type conductive polymer. For example, the n-type metal oxide may form a charge-transfer complex with the p-type conductive polymer to facilitate hole transport more smoothly.

The n-type metal oxide may be used in the form of nanoparticles, which may be advantageous in forming a uniform mixed layer by increasing dispersibility in a solution.

An example of the n-type metal oxide is molybdenum oxide (MoOₓ). In addition, tungsten oxide (WO₃), vanadium oxide (V₂O₅), nickel oxide (NiOₓ), and the like may be used, but are not limited thereto.

### Perfluorinated Compound

The perfluorinated compound may perform a key role in inducing self-assembly within the composite layer.

The perfluorinated compound may have a very low surface energy by including a plurality of fluorine (F) atoms in its molecular structure. Due to these characteristics, during the solution process and the drying process, the perfluorinated compound may show a tendency to spontaneously move toward the air-solution interface, that is, the uppermost surface of the composite layer, in order to find a thermodynamically stable state.

An example of the perfluorinated compound is perfluorinated sulfonic acid (PFSA). In addition to PFSA, various perfluorinated compounds having low surface energy, such as perfluorocarboxylic acid and perfluoroalcohol, may be used, but are not limited thereto.

### Single Composite Layer

The hole transport layer of an embodiment is a ‘single composite layer’ formed by a single coating process from a single solution in which the three components are mixed. Although this composite layer is physically a single layer, it may internally have a vertical composition gradient with differentiated functions.

For example, spontaneous vertical phase separation may occur due to a difference in surface energy between components and a difference in affinity with a solvent that occur during the drying process of the coated solution. The perfluorinated compound having a low surface energy may move to the top of the layer (the second surface, the side in contact with the emissive layer) to form a rich concentration. On the other hand, the p-type conductive polymer and the n-type metal oxide, which are relatively hydrophilic or have a high density, may be mainly distributed at the bottom of the layer (the first surface, the side in contact with the electrode).

As a result of this self-assembly phenomenon, the hole transport layer may have a structure in which the composition gradually changes from the bottom to the top, and the energy level change according to such a vertical composition gradient may be confirmed through depth-profiling analysis using ultraviolet photoelectron spectroscopy (UPS).

Bottom region of the single composite layer (near the first surface): The n-type metal oxide and the p-type conductive polymer are rich, so a charge-transfer complex may be formed. This region has high electrical conductivity and may facilitate hole transport from the anode.

Upper region of the single composite layer (near the second surface): The perfluorinated compound is rich, so it may have a high work function and insulation. The high work function serves to lower the hole injection barrier into the emissive layer, and the insulation may effectively suppress the phenomenon of exciton quenching at the interface with the emissive layer.

As a result, although the hole transport layer of an embodiment is a single layer formed by a single process, it may simultaneously implement conflicting properties of a conductive interior and an insulating surface. This may lower the driving voltage of the device and dramatically improve luminous efficiency and life-span.

### (Method for Preparing Hole Transport Layer)

An embodiment provides a method for preparing a hole transport layer for an optoelectronic device, which includes: preparing a raw material mixture including a p-type conductive polymer, an n-type metal oxide, and a perfluorinated compound; coating the raw material mixture; and drying the raw material mixture coating solution, wherein in the drying, a single composite layer having a vertical composition gradient is formed, and in the composition gradient, a concentration of the perfluorinated compound gradually increases and a concentration of the n-type metal oxide gradually decreases along a thickness direction from a first surface toward a second surface of the single composite layer.

According to this, it is possible to provide an effective means for reproducibly synthesizing the hole transport layer for an optoelectronic device of the above-described embodiment.

Hereinafter, the method for preparing the hole transport layer for the optoelectronic device of an embodiment will be described in detail step by step.

### Step of Preparing Raw Material Mixture

This step may be a process of preparing a raw material mixture (ink or solution) for coating by uniformly mixing or dispersing three key elements constituting the hole transport layer, which are a p-type conductive polymer, an n-type metal oxide, and a perfluorinated compound, in a solvent.

The n-type metal oxide nanoparticles may be separately synthesized prior to the preparation of the raw material mixture. For example, an n-type metal oxide (e.g., MoOₓ) nanoparticle dispersion may be prepared by redox reaction of an n-type metal precursor (e.g., molybdenum precursor) and an oxidant (e.g., hydrogen peroxide solution) in an alcohol-based solvent (e.g., ethanol, isopropanol). At this time, the oxidation state or size of the nanoparticles may be controlled by adjusting the ratio between the precursors.

Next, a uniform raw material mixture may be prepared by putting the prepared n-type metal oxide nanoparticle dispersion, a p-type conductive polymer in the form of a commercial aqueous dispersion (e.g., PEDOT:PSS), and a perfluorinated compound solution (e.g., PFSA solution) into one container and through stirring or ultrasonic treatment. Since the structure and properties of the final hole transport layer may vary depending on the composition ratio of each component determined in this step, precise control may be required.

### Step of Coating Raw Material Mixture

This step may be a process of forming a thin liquid film by coating the prepared raw material mixture onto a substrate of an optoelectronic device, for example, a substrate on which an anode is formed.

Since the method for preparing of an embodiment is based on a solution process, various coating technologies may be applied. For the solution process, methods such as spin coating, doctor blading, inkjet printing, slot-die coating, screen printing, and roll-to-roll may be used. Such a solution process may be advantageous for manufacturing large-area devices at low cost without expensive vacuum deposition equipment.

### Drying Step

This step is a process of forming a solid thin film by evaporating a solvent from the coated liquid film, and may be the most important step in which the vertical composition gradient, which is the core of an embodiment, is spontaneously formed.

While the liquid film is drying, the perfluorinated compound molecules having a low surface energy may spontaneously migrate to the surface in contact with the air, that is, the top of the thin film, in order to form a thermodynamically stable state. On the other hand, the p-type conductive polymer and the n-type metal oxide, which have relatively high surface energy or good affinity with the substrate, may remain in the lower and middle regions of the thin film.

By such self-assembly and vertical phase separation phenomena, after the solvent is completely evaporated, a vertical gradient structure having different compositions at the top and bottom may be formed inside one solid thin film. The drying process may be generally performed by annealing using a hot plate or the like at a specific temperature (e.g., 100 to 150° C.) for a specific time (e.g., 5 to 30 minutes). This annealing process may serve to completely remove residual solvent and complete a stable thin film structure.

### (Optoelectronic Device)

An embodiment provides an optoelectronic device including the hole transport layer according to the above-described embodiment.

By employing the high-performance hole transport layer of the above-described embodiment, it is possible to provide an optoelectronic device having a low driving voltage and improved luminous efficiency and life-span.

### Optoelectronic Device

The optoelectronic device may include, for example, various devices in which perovskite materials may be usefully used, such as a perovskite light emitting device, a solar cell, and a photodetector.

When the optoelectronic device is a light emitting device, it may include an anode, a cathode, and an emissive layer located between the anode and the cathode as a basic structure. In order to improve the efficiency and stability of the device, it may further include one or more functional layers interposed between the emissive layer and the electrodes.

Hereinafter, other configurations of the optoelectronic device will be described.

### Anode

The anode is an electrode for injecting holes and may be formed of a conductive material having a high work function. In the case of a bottom emission device that emits light from the substrate side, the anode may need to be transparent so that light may pass through. For example, the anode may be made of a transparent conductive oxide such as indium tin oxide (ITO), indium zinc oxide (IZO), or the like.

### Cathode

The cathode is an electrode for injecting electrons and may be formed of a conductive material having a low work function. For example, the cathode may include a metal such as aluminum (Al), magnesium (Mg), calcium (Ca), silver (Ag), or an alloy thereof.

### Hole Transport Layer (HTL)

The hole transport layer (HTL) is located between the anode and the emissive layer and may serve to help holes injected from the anode to smoothly move to the emissive layer.

An embodiment relates to exactly such a hole transport layer, and by having a vertical composition gradient formed through self-assembly as described above, it is possible to simultaneously implement efficient hole transport and interfacial exciton quenching suppression properties.

### Electron Transport Layer (ETL)

The electron transport layer (ETL) is located between the cathode and the emissive layer and may serve to efficiently transport electrons injected from the cathode to the emissive layer.

### Emissive Layer (EML)

The emissive layer may be a key component of the device, where holes and electrons respectively injected from an anode and a cathode recombine to emit light. In an embodiment, the emissive layer may be formed including perovskite nanocrystals.

### Solution Process

The thin film or functional layer according to an embodiment may be formed through a solution process. The solution process may be a method of preparing a solution by dissolving or dispersing a material constituting each layer in an appropriate solvent, and then coating and drying it on a substrate to form a thin film. For example, in the solution process, methods such as spin coating, doctor blading, inkjet printing, and slot-die coating may be used. Such a solution process may be advantageous in manufacturing large-area devices at low cost without expensive vacuum deposition equipment.

Hereinafter, Examples and Comparative Examples of the present invention are described. However, the following examples are only an example of the present invention, and the present invention is not limited to the following examples.

### Preparation Example: MoOₓ Nanoparticle Dispersion

### Preparation Example 1: High-Oxidant MoOₓ (SOH—H) Nanoparticle Dispersion

After dissolving molybdenum (V) ethoxide in an ethanol solvent, 1 mole of hydrogen peroxide solution (H₂O₂) relative to the molybdenum precursor was added. The mixed solution was stirred at room temperature for 12 hours to 144 hours. As the reaction progressed, the solution turned yellow, whereby an SOH—H dispersion in which MoOₓ (where x is about 3) nanoparticles having a high ratio of Mo⁶⁺ were dispersed was obtained.

### Preparation Example 2: Low-Oxidant MoOₓ (SOH-L) Nanoparticle Dispersion

The same method as in Preparation Example 1 was used, except that only 0.5 mole of hydrogen peroxide solution relative to the molybdenum precursor was added. The reaction solution turned dark blue, and an SOH-L dispersion in which MoOₓ (where x is about 2.5) nanoparticles having a relatively high ratio of Mo⁵⁺ were dispersed was obtained.

### Example: Self-Assembled Hole Transport Layer Solution Including Metal Oxide

### Example 1: Hole Transport Layer Solution Using High-Oxidant MoOₓ (SOH—H)

PEDOT:PSS (Clevios™ P VP AI 4083; PEDOT:PSS, weight ratio 1:6) was prepared as a p-type conductive polymer, and Nafion (Sigma Aldrich; tetrafluoroethylene-perfluoro-3,6-dioxa-4-methyl-7-octene-sulfonic acid copolymer) was prepared as a perfluorinated compound. An organic mixed solution was prepared by mixing the PEDOT:PSS and Nafion (PFSA) in a solvent. A final hole transport layer coating solution was prepared by mixing the previously prepared SOH—H dispersion and the organic mixed solution. At this time, based on solid content, the weight ratio of MoOₓ (SOH—H): PEDOT:PSS:PFSA was adjusted to be about 7:60:100. (This corresponds to about 11.7 parts by weight of MoOₓ and about 166.7 parts by weight of PFSA relative to 100 parts by weight of PEDOT:PSS.)

### Example 2: Hole Transport Layer Solution Using Low-Oxidant MoOₓ (SOH-L)

A coating solution was prepared using the SOH-L dispersion prepared in Preparation Example 2 instead of the SOH—H dispersion, while keeping all other compositions the same as in Example 1.

### Comparative Example 1: Hole Transport Layer (SOP-HIL 13) Solution without n-Type Metal Oxide

A coating solution was prepared by mixing such that the weight ratio of PEDOT:PSS:PFSA was the same as in Example 1.

### Comparative Example 2: Hole Transport Layer (SOP-HIL 3) Solution without n-Type Metal Oxide and with Low PFSA Amount

A coating solution was prepared by mixing such that the weight ratio of PEDOT:PSS:PFSA was about 12:5.

### Comparative Example 3: Hole Transport Layer (SOP-HIL 38) Solution without n-Type Metal Oxide and with High PFSA Amount

A coating solution was prepared by mixing such that the weight ratio of PEDOT:PSS:PFSA was about 1:5.

### Manufacture of Organic Light-emitting Film

A glass substrate was ultrasonically cleaned with isopropyl alcohol and acetone for 30 minutes each. Immediately before use, UV-ozone treatment was performed for 20 minutes to remove organic matter on the surface and ensure hydrophilicity.

On the cleaned ITO substrate, each hole transport layer solution prepared in Comparative Examples 1 to 3 was spin-coated at 4000 rpm for 90 seconds and heat-treated on a hot plate at 150° C. for 30 minutes to form a hole transport layer (HTL).

On each of the formed hole transport layers, a light-emitting film was prepared by spin-coating an organic emitter solution to form an emissive layer.

### Manufacture of Perovskite Light-Emitting Device

FIG. 1 is a schematic view showing the structure of a perovskite light-emitting device including a hole transport layer according to an embodiment of the present invention. A glass substrate on which patterned indium tin oxide (ITO) was deposited was prepared. The substrate was ultrasonically cleaned with isopropyl alcohol and acetone for 30 minutes each. Immediately before use, UV-ozone treatment was performed for 20 minutes to remove organic matter on the surface and ensure hydrophilicity.

On the cleaned ITO substrate, each hole transport layer solution prepared in Examples 1 to 2 and Comparative Example 1 was spin-coated at 4000 rpm for 90 seconds and heat-treated on a hot plate at 150° C. for 30 minutes to form a hole transport layer (HTL).

On each of the formed hole transport layers, an emissive layer was formed by spin-coating a perovskite nanocrystal (MHP NC) solution. Then, TPBi was deposited as an electron transport layer to a thickness of 50 nm on the emissive layer using vacuum thermal deposition equipment, and then lithium fluoride (LiF) was sequentially deposited to a thickness of 1 nm as an electron injection layer, and finally aluminum (Al) was sequentially deposited to a thickness of 100 nm as a cathode electrode to complete the manufacture of a perovskite light-emitting device.

### Evaluation Example 1: Microstructure and Crystallinity Analyses of MoOₓ Nanoparticles

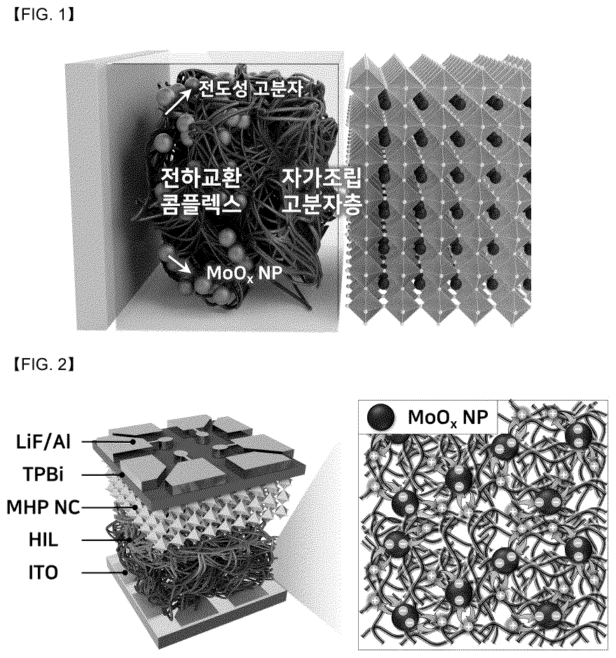

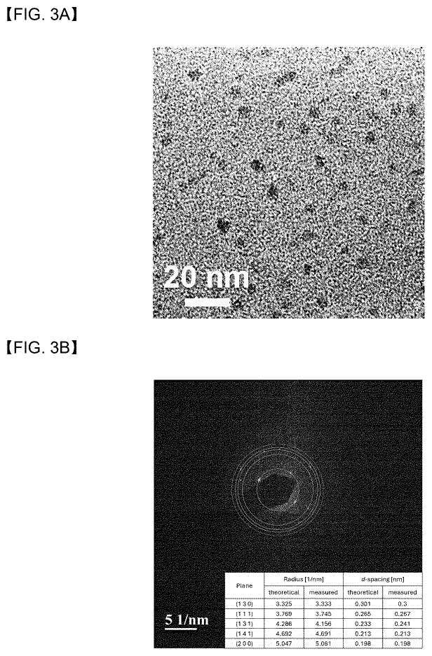

The microstructure and crystallinity of metal oxide particles (MoOₓ) included in the prepared hole transport layer were confirmed through transmission electron microscopy (TEM) and selected area electron diffraction (SAED) analysis. Referring to FIG. 2, as a result of TEM observation, the manufactured metal oxide showed a form in which nanoparticles having a size of about 2 to 10 nm were evenly dispersed. In addition, as a result of SAED pattern analysis, clear diffraction rings were observed, confirming that the corresponding particles have crystallinity.

Specifically, d-spacing was calculated through the radius of the measured diffraction pattern. As a result of comparing this with theoretical values for crystal planes such as (130), (111), and (131) registered in the Crystallography Open Database (COD), it was confirmed that the measured values match within the error range, and the results are shown in Table 1.

TABLE 1

| | |
|---|---|
| Radius [1/nm] | d-spacing [nm] |

| Plane | theoretical | measured | theoretical | measured |
|---|---|---|---|---|
| (130) | 3.325 | 3.333 | 0.301 | 0.3 |
| (111) | 3.769 | 3.745 | 0.265 | 0.267 |
| (131) | 4.286 | 4.156 | 0.233 | 0.241 |
| (141) | 4.692 | 4.691 | 0.213 | 0.213 |
| (200) | 5.047 | 5.061 | 0.198 | 0.198 |

### Evaluation Example 2: Analysis of Oxidation State and Chemical Properties of MoOₓ Dispersion

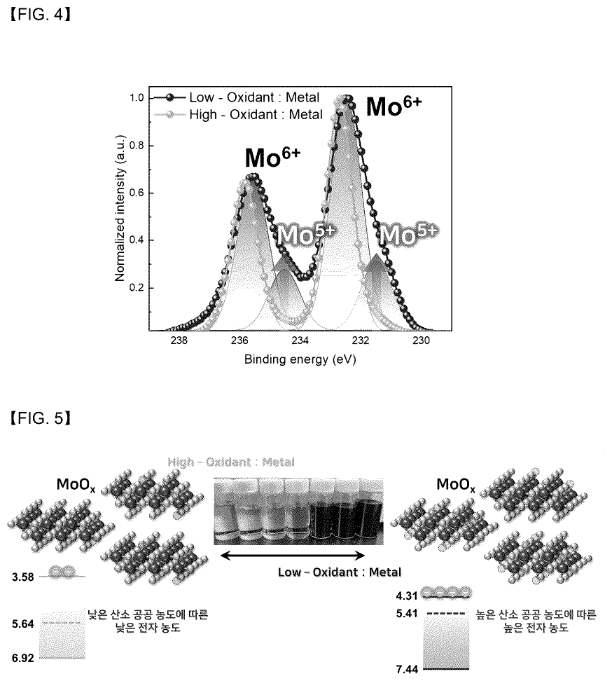

The chemical composition and oxidation number of molybdenum (Mo) in the SOH—H dispersion and the SOH-L dispersion prepared in Preparation Example 1 and Preparation Example 2, respectively, were analyzed using X-ray Photoelectron Spectroscopy (XPS), and the resulting spectra are shown in FIG. 3. Referring to FIG. 3, the change in the spectrum shape of the obtained Mo 3d peak may be confirmed. Unlike the SOH—H dispersion in which the characteristics of Mo⁶⁺ are dominant, a new shoulder peak was clearly observed at a lower binding energy position than the Mo⁶⁺ peak in the spectrum of the SOH-L dispersion. This means generation and intensity increase of the Mo⁵⁺ component, which is in a reduced state.

That is, the SOH—H dispersion in which the hydrogen peroxide solution ratio was set high maintained a high oxidation state mainly with the Mo⁶⁺ state, but the SOH-L dispersion showed relatively clear Mo⁵⁺ components, showing reduced characteristics compared to SOH—H. This difference in chemical states is also consistent with the visual observation results of the dispersions.

FIG. 4 is a photograph of each prepared dispersion, and it was confirmed that the SOH-L dispersion in which the generation of Mo⁵⁺ was confirmed had a dark blue color, while the SOH—H dispersion in which the Mo⁶⁺ state was dominant showed a yellow color.

### Evaluation Example 3: Electronic Structure and Energy Level Analyses of MoOₓ Dispersion

Referring to FIG. 5, the work function and valence band levels of the SOH—H dispersion and the SOH-L dispersion prepared in Preparation Example 1 and Preparation Example 2, respectively, were measured using ultraviolet photoelectron spectroscopy (UPS). The work function was calculated through the secondary electron cut-off region of the measured spectrum, and the ionization potential (IP) was confirmed through the valence band onset. As a result of the evaluation, the SOH—H dispersion having a high oxidation number showed a higher work function value than the SOH-L dispersion. Detailed energy level values are shown in Table 2.

TABLE 2

| | | Ionization potential |
|---|---|---|
| | Work function (eV) | (eV) |
| Preparation Example 1 | 5.64 | 6.92 |
| (SOH-H) | | |
| Preparation Example 2 | 5.41 | 7.44 |
| (SOH-L) | | |

As shown in Table 2 above, it was confirmed that the SOH—H dispersion having a high Mo⁶⁺ content forms a Fermi level of 5.64 eV, which is further from the vacuum level. On the other hand, the SOH-L dispersion rich in Mo⁵⁺ generated due to relatively oxygen deficiency showed a work function of 5.41 eV, and the electron concentration was formed high. Referring to FIG. 6, the energy band alignment and charge exchange mechanism between PEDOT:PSS (work function: 5.0 to 5.2 eV) and the dispersion may be seen. The SOH-L dispersion with higher electron concentration showed more active and efficient charge exchange characteristics with the PEDOT:PSS layer than the SOH—H dispersion with lower electron concentration. This may be interpreted as the energy level created by oxygen vacancies providing a path that lowers the barrier required for charge transfer, and consequently, charge transport efficiency at the interface is improved.

### Evaluation Example 4: Confirmation of Vertical Phase-Separated Structure and Gradual Work Function Change of Hole Transport Layer

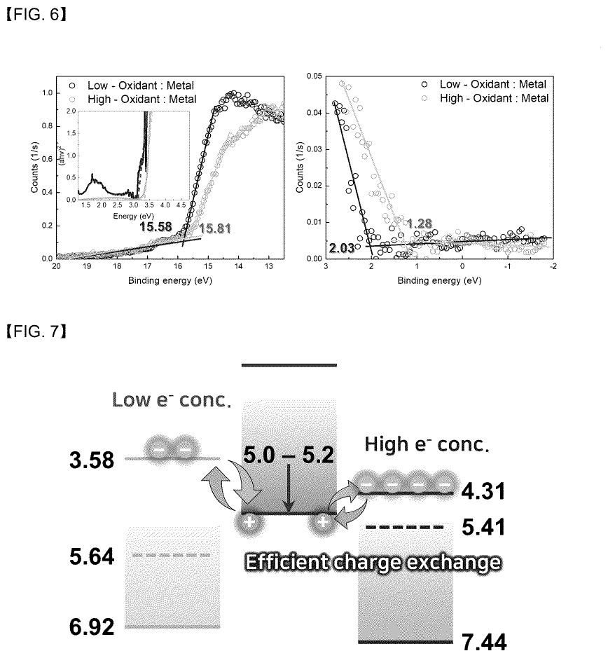

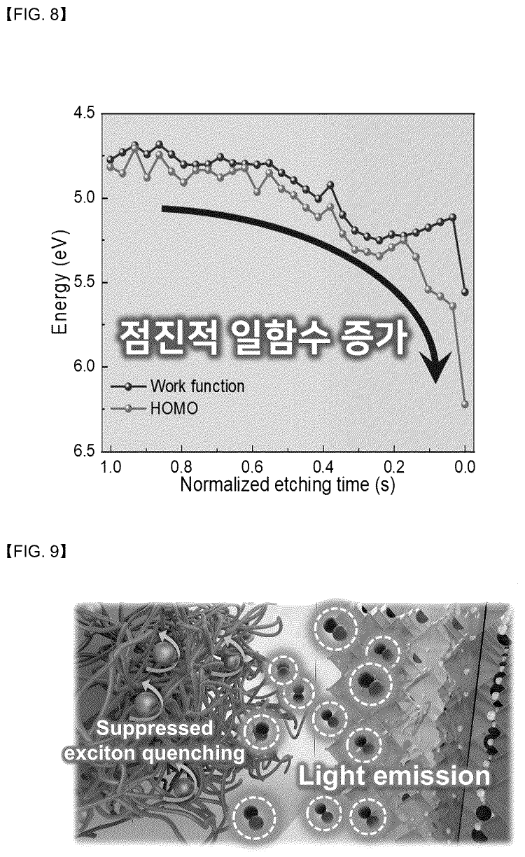

In order to confirm the vertical distribution of components in the hole transport layer of Example 2 and the resulting energy level changes, depth-profiling UPS analysis was performed. Referring to FIG. 7, as a result of the analysis, the highest work function value was observed at the surface of the thin film due to the high ionization energy of the perfluorinated compound. Thereafter, as the sputtering time increased and it entered the inside of the thin film, the work function showed a tendency to gradually decrease. This proves that PFSA having a low surface energy was self-assembled to the thin film surface to form a vertical phase-separated structure, and it was confirmed that efficient hole delivery to the emissive layer is possible by mitigating the hole injection/transport barrier through such a gradient energy structure.

### Evaluation Example 5: Evaluation of Exciton Quenching Suppression Properties of Hole Transport Layer at the Interface

The performance of organic light-emitting films manufactured using Comparative Examples 1 to 3 and a reference hole transport layer was evaluated. The PL life-span was analyzed by measuring the attenuation of light emitted after exciting the emissive layer with a pulse laser having a wavelength of 405 nm using a time-correlated single photon counting (TCSPC) device. The evaluation results are shown in Table 3. Referring to FIG. 8, the interface schematic view of the hole transport layer according to the present invention may be confirmed. It can be seen that by disposing a perfluorinated compound having a low surface energy at the interface with the emissive layer, the interfacial exciton quenching phenomenon in which excitons in the emissive layer move to the hole transport layer and disappear is effectively suppressed.

TABLE 3

| | PL life-span (ns) |
|---|---|
| Comparative Example 1 | 306.2 |
| (optimal PFSA ratio) | |
| Comparative Example 2 | 236.0 |
| (PFSA↓) | |
| Comparative Example 3 | 469.9 |
| (PFSA↑) | |
| PEDOT:PSS (reference) | 262.7 |

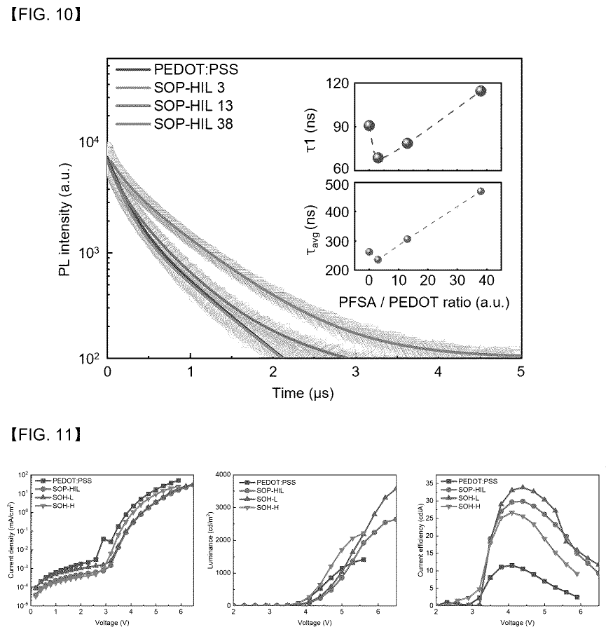

Referring to FIG. 9, as shown in Table 3 above, as the composition of the perfluorinated compound increased, the interfacial exciton quenching decreased and the PL life-span tended to increase. In particular, in the reference film (PEDOT:PSS) without a perfluorinated compound and in Comparative Example 2 with almost no perfluorinated compound, it can be seen that the interfacial exciton quenching is serious and the PL life-span is significantly low.

### Evaluation Example 6: Performance Evaluation of Perovskite Light-Emitting Device

The performance of perovskite light-emitting devices manufactured using each hole transport layer was evaluated. In order to confirm the luminance and current efficiency of the device, current-voltage-luminance (J-V-L) characteristics were measured using a source meter (Keithley 2400) and a spectroradiometer (Konica Minolta CS-2000). The evaluation results are shown in Table 4.

TABLE 4

| | Maximum current | Maximum |
|---|---|---|
| | efficiency (cd/A) | luminance (cd/m²) |
| Example 1 (SOH-H) | 26.7 | 2219 |
| Example 2 (SOH-L) | 33.9 | 3702 |
| Comparative Example 1 | 29.9 | 2675 |
| (No MoOₓ) | | |
| PEDOT:PSS (reference) | 11.5 | 1412 |

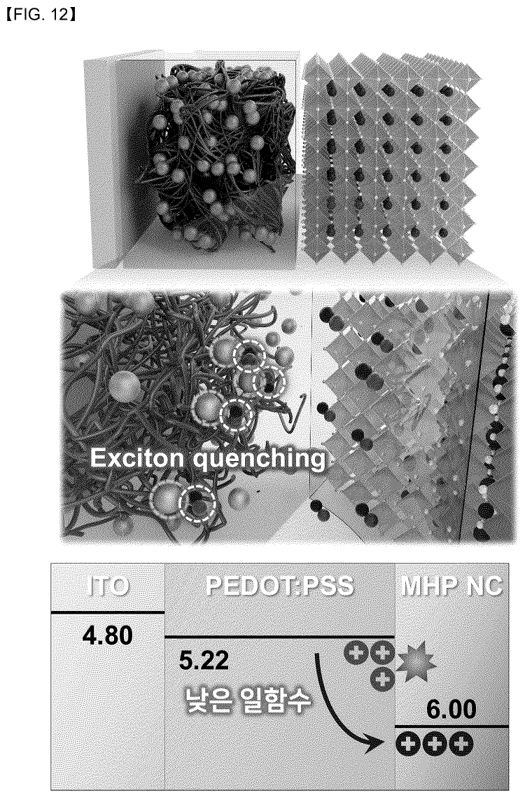

Referring to FIG. 10, as shown in Table 4 above, Example 2, in which the oxidation degree of MoOₓ is low, showed the highest current efficiency and luminance, and it decreased in Example 1, in which the composition ratio deviated from the optimum ratio. FIG. 11 is a schematic view and an energy band diagram showing the limitations of conventional metal oxide and polymer mixing. Referring to FIG. 11, in the case of the reference device (PEDOT:PSS) without a perfluorinated compound, it can be confirmed that serious exciton quenching occurs at the interface, and it can be confirmed that current efficiency and luminance are lowered because the hole injection barrier into the emissive layer (6.00 eV) is high due to the low work function (5.22 eV). In addition, in the case of Comparative Example 1 without an n-type metal oxide, it showed better performance than the reference device (PEDOT:PSS) due to the interface improvement effect by the perfluorinated compound, but it was confirmed that the current efficiency and luminance remained at a lower level than Example 2, in which the hole transport capability was reinforced through a low oxidation state metal oxide.

### CONCLUSION

Comprehensively analyzing the results of Evaluation Examples 1 to 6, a clear causal relationship between the unique structural characteristics of the hole transport layer of an embodiment and the resulting improvement in device performance may be confirmed.

As confirmed in the depth-profiling UPS analysis of Evaluation Example 4, the examples successfully formed a ‘vertical composition gradient’ having a bottom rich in n-type metal oxide and a surface rich in perfluorinated compound even with only a single coating process. This has the effect of minimizing the hole injection barrier by forming an ideal ‘gradient energy level’ in which the work function gradually changes from the thin film surface toward the interior.

In terms of function, this double structure simultaneously satisfies conflicting required properties. The low oxidation state (Mo⁵⁺)-based metal oxide confirmed in Evaluation Examples 2 and 3 serves as an efficient hole transport path inside the thin film, and as proved in Evaluation Example 5, the perfluorinated compound layer concentrated on the surface effectively suppressed exciton quenching at the interface with the emissive layer, thereby contributing to securing a long PL life-span.

As a result, as in the device performance evaluation results of Evaluation Example 6, these structural advantages led to improvements in current efficiency and luminance of the actual device. On the other hand, it was confirmed that simple interface formation such as reference PEDOT:PSS without composition gradient or Comparative Example 1 does not simultaneously perform these complex functions of charge transport and quenching suppression, resulting in inferior performance. Accordingly, it can be seen that control of the oxidation state of the n-type metal oxide and optimized composition ratio of each component induce self-assembly to form an ideal vertical functional gradient structure, which is a key factor in achieving high performance of the device.

While preferred embodiments of the present invention have been described above, the present invention is not limited thereto, and various modifications may be made within the scope of the claims, the detailed description of the invention, and the accompanying drawings, which also naturally fall within the scope of the present invention.

1. An embodiment provides a hole transport layer for an optoelectronic device, which is a single composite layer having a first surface and a second surface located opposite the first surface;
wherein the single composite layer
comprises a p-type conductive polymer, an n-type metal oxide, and a perfluorinated compound, and
has a vertical composition gradient in which a concentration of the n-type metal oxide gradually decreases and a concentration of the perfluorinated compound gradually increases along a thickness direction from the first surface toward the second surface.

2. The hole transport layer for the optoelectronic device of claim 1, wherein
the n-type metal oxide is molybdenum oxide (MoOₓ).

3. The hole transport layer for the optoelectronic device of claim 1, wherein
the p-type conductive polymer is PEDOT:PSS (poly(3,4-ethylenedioxythiophene) polystyrene sulfonate).

4. The hole transport layer for the optoelectronic device of claim 1, wherein
the perfluorinated compound is perfluorinated sulfonic acid (PFSA).

5. The hole transport layer for the optoelectronic device of claim 1, wherein
in a region adjacent to the first surface, the p-type conductive polymer and the n-type metal oxide form a charge-transfer complex.

6. The hole transport layer for the optoelectronic device of claim 1, wherein
the second surface has a higher electrical resistance than the first surface.

7. The hole transport layer for the optoelectronic device of claim 1, wherein
the single composite layer further has an energy level gradient in which a work function gradually increases along a thickness direction from the first surface toward the second surface.

8. The hole transport layer for the optoelectronic device of claim 1, wherein
based on 100 parts by weight (or parts by mole) of the p-type conductive polymer
5 to 20 parts by weight of the n-type metal oxide nanoparticles are included, and
50 to 200 parts by weight of the perfluorinated compound is included.

9. A method for preparing a hole transport layer for an optoelectronic device, comprising
preparing a raw material mixture comprising a p-type conductive polymer, an n-type metal oxide, and a perfluorinated compound;
coating the raw material mixture; and
drying the raw material mixture coating solution,
wherein in the drying, a single composite layer having a vertical composition gradient is formed, and
in the composition gradient, a concentration of the perfluorinated compound gradually increases and a concentration of the n-type metal oxide gradually decreases along a thickness direction from a first surface toward a second surface of the single composite layer.

10. The method for preparing the hole transport layer for the optoelectronic device of claim 9, wherein
before preparing the raw material mixture,
the method further comprises preparing n-type metal oxide nanoparticles using a redox reaction of an n-type metal precursor and a hydrogen peroxide precursor.

11. The method for preparing the hole transport layer for the optoelectronic device of claim 10, wherein
in the preparation of the n-type metal oxide nanoparticles,
a molar ratio of the n-type metal precursor and the hydrogen peroxide precursor is 1:0.5 to 1:1.5.

12. The method for preparing the hole transport layer for the optoelectronic device of claim 10, wherein
a preparation reaction of the n-type metal oxide nanoparticles is performed in an alcohol solvent.

13. The method for preparing the hole transport layer for the optoelectronic device of claim 9, wherein
the drying of the raw material mixture coating solution is performed at a temperature range of 120 to 180° C. for 20 to 40 minutes.

14. An optoelectronic device comprising the hole transport layer of claim 1.

15. The optoelectronic device of claim 14, wherein
the optoelectronic device is a perovskite light-emitting device.
